(19) United States
(12) Patent Application Publication
(10) Pub. No.: US 2006/0172533 A1
(43) Pub. Date: Aug. 3, 2006

(54) Method of fabricating printed circuit board

(75) Inventors: Byung Kook Sun, Seoul (KR); Takayuki Haze, Kyoto-shi (JP); Seung Chul Kim, Chungcheongbuk-do (KR)

Correspondence Address: DARBY & DARBY P.C., P. O. BOX 5257, NEW YORK, NY, 10150-5257, US

(73) Assignee: Samsung Electro-Mechanics Co., Ltd., Kyunggi-do (KR)

(21) Appl. No.: 11/138,490

(22) Filed: May 25, 2005

(30) Foreign Application Priority Data
Jan. 28, 2005 (KR) 10-2005-0008028

(51) Int. Cl. H01L 21/44

(52) U.S. Cl. 438/675

(57) ABSTRACT

A method of fabricating a printed circuit board having a fine circuit pattern and a via hole having no residue by forming the circuit pattern using an imprinting process and forming the via hole using a laser.

The present application claims priority under 35 U.S.C. §119 to Korean Patent Application No. 2005-8028 filed on Jan. 28, 2005. The content of the application is incorporated herein by reference in its entirety.

### BACKGROUND OF THE INVENTION

1. Field of the Invention

The present invention relates, generally, to a method of fabricating a printed circuit board (PCB), and more particularly, to a method of fabricating a PCB having a fine circuit pattern and a via hole in which no residue exists, by forming the circuit pattern using an imprinting process and forming the via hole using a laser.

2. Description of the Related Art

Recently, to correspond to semiconductor chips requiring high densities and high signal transfer speeds, techniques for directly mounting a semiconductor chip on a PCB have been increasingly used, instead of CSP (Chip-Sized Package) mounting or wire bonding mounting. Consequently, with the aim of directly mounting the semiconductor chip on the PCB, highly reliable PCBs having high densities, capable of being used with highly dense semiconductors, must be developed.

Requirements for the PCB having high density and reliability, which are closely associated with specifications of semiconductor chips, include fine circuits, high electrical properties, high speed signal transfer structures, high functionality, etc. Hence, techniques for fabricating a PCB having a fine circuit pattern and a micro-via hole that fulfills the above requirements are needed.

In general, the method of fabricating the PCB uses photo-lithography exhibiting high producibility and low fabrication costs.

The method of fabricating the PCB using photo-lithography is exemplified by subtractive, full additive, and semi-additive methods. Of the above methods, the semi-additive method is receiving attention, because it is able to form the finest circuit pattern.

FIGS. 1a to 1i are sectional views sequentially showing a process of fabricating a PCB using a conventional semi-additive technique.

In FIG. 1a, a copper clad laminate (CCL) 110, which has an insulating resin layer 111 and a circuit pattern 112 and a lower land 113 for a via hole formed on the insulating resin layer 111, is prepared, and then an insulating layer 120 is laminated on the CCL 110.

In FIG. 1b, the insulating layer 120 is processed using a laser to form a via hole a for circuit connection between layers. Subsequently, a desmearing process is carried out to remove a smear created on the lower land 113 and the inner wall 121 of the via hole a by the insulating layer 120 melted due to heat generated when forming the via hole a using a laser.

In FIG. 1c, an electroless copper plated layer 130 being about 1 μm thick or more is formed on the insulating layer 120 and the inner wall 121 and the lower land 113 of the via hole a, to electrically connect the layers and form the circuit pattern on the insulating layer 120.

In FIG. 1d, a dry film 150 is applied on the electroless copper plated layer 130.

In FIG. 1e, an art work film 160 having a predetermined pattern is attached to the dry film 150 and then exposed to ultraviolet rays 170. As such, ultraviolet rays are passed through a non-printed portion 161 of the art work film 160, thereby forming a cured portion 151 of the dry film 150 under the art work film 160. On the other hand, ultraviolet rays 170 are not passed through a printed black portion 162 of the art work film 160, forming a non-cured portion 152 of the dry film 150 under the art work film 160.

As such, the predetermined pattern of the art work film 160 includes patterns corresponding to the circuit pattern, the inside of the via hole, and the upper land for the via hole, which are to be formed in the following processes.

In FIG. 1f, the art work film 160 is removed, and then a developing process is performed to remove the non-cured portion 152 of the dry film 150, whereby only the cured portion 151 of the dry film 150 remains.

In FIG. 1g, the cured portion 151 of the dry film 150 is used as a plating resist to perform a copper electroplating process. Thereby, copper electroplated layers 141 and 142 are formed to a thickness of about 10-20 μm on a circuit pattern 131 having no plating resist pattern, an inner wall 132 of the via hole a, and an upper land 133 and a lower land 134 for the via hole a.

In FIG. 1h, the cured portion 151 of the dry film 150 is removed from the electroless copper plated layer 130.

In FIG. 1i, a flash etching process, which serves to spray an etching solution on the electroless copper plated layer 130 and the copper electroplated layers 141 and 142, is conducted to remove the electroless copper plated layer 130 with the exception of the circuit pattern regions 131 and 141 and the via hole regions 132, 133, 134 and 142.

Subsequently, laminating an insulating layer, forming a circuit pattern using a semi-additive technique, forming a solder resist, nickel/gold plating, and processing an outer appearance are carried out to conventionally fabricate a PCB 100.

However, the conventional fabrication method of the PCB using a semi-additive process is disadvantageous in that because the flash etching process is performed for a relatively long time to remove the unnecessary electroless copper plated layer 130, the circuit pattern regions 131 and 141 (in particular, edge portions of the circuit pattern regions 131 and 141) may be over-etched.

Thus, the circuit pattern regions 131 and 141 may be delaminated or have non-uniform morphology.

In particular, the over-etching problems of the circuit pattern become more severe in proportion to the fineness of the circuit pattern of the PCB.

To solve the problems, Japanese Patent Laid-open Publication Nos. 2001-320150 and 2002-57438 disclose a method of fabricating a PCB using an imprinting process.

FIGS. 2a to 2e are sectional views sequentially showing a process of fabricating a PCB using a conventional imprinting technique, which is disclosed in Japanese Patent Laid-open Publication No. 2001-320150.

In FIG. 2a, a stamper 201 having a negative pattern corresponding to a fine circuit pattern is mounted on a tool foil (not shown).

In FIG. 2b, a thermosetting epoxy resin is injected into the tool foil to conduct a transfer molding process. Thereby, a resin substrate 202 having a circuit pattern transferred thereon is obtained.

In FIG. 2c, copper is deposited to a thickness of about 0.1 μm on the resin substrate 202 using a sputtering device to increase the strength of adhesion to the subsequent plated layer. Thereafter, a copper plating process is carried out to form a copper plated layer 203 being about 15 μm thick.

In FIG. 2d, the plated surface formed throughout one surface of the resin substrate 202 is polished using a polisher to which a polishing slurry is supplied until the resin portions between the recesses for the substrate 202 are exposed.

In FIG. 2e, a fine circuit pattern having a line width of about 10 μm and a thickness of about 9 μm is obtained.

The fabrication method of the PCB disclosed in Japanese Patent Laid-open Publication No. 2001-320150 is advantageous because the fine circuit pattern can be formed using the stamper 201 having the negative pattern corresponding to the fine circuit pattern.

However, in the case in which the via hole for connection between the circuit layers is formed by the fabrication method of the PCB disclosed in Japanese Patent Laid-open Publication No. 2001-320150, the resin residue may remain on the lower land.

Further, since the resin residue remaining on the lower land for the via hole is not completely removed by a desmearing process spraying water at a high pressure of 70 kg/cm² or more, it acts as a resistance when the circuit layers are electrically connected, thus decreasing the electrical properties of the PCB.

### SUMMARY OF THE INVENTION

Accordingly, the present invention has been made keeping in mind the above problems occurring in the related art, and an object of the present invention is to provide a method of fabricating a PCB having a fine circuit pattern and a via hole in which no residue exists.

In order to accomplish the above object, the present invention provides a method of fabricating a printed circuit board, which includes the steps of (A) laminating a semi-cured insulating layer on a base substrate having a first circuit pattern and a lower land for a via hole, and matching a tool foil having a predetermined pattern corresponding to a second circuit pattern to the base substrate on which the insulating layer is laminated; (B) imprinting the tool foil on the insulating layer and completely curing the insulating layer, to form a recess for the second circuit pattern in the insulating layer; (C) forming a via hole through the insulating layer on the lower land of the base substrate using a laser; (D) forming an electroless plated layer on the insulating layer, the recess for the second circuit pattern, and the inner wall of the via hole; (E) forming an electroplated layer on the electroless plated layer; and (F) polishing the electroless plated layer and the electroplated layer until the insulating layer is exposed.

In an embodiment, the step (B) of the above method includes the steps of (B-1) imprinting the tool foil on the insulating layer; (B-2) removing the tool foil from the insulating layer, thereby forming the recess for the second circuit pattern in the insulating layer; and (B-3) curing the insulating layer completely.

In another embodiment, the step (B) of the above method includes the steps of (B-1) imprinting the tool foil on the insulating layer, while heating at least one of the insulating layer and the tool foil to completely cure the insulating layer; and (B-2) removing the tool foil from the insulating layer, thereby forming the recess for the second circuit pattern in the insulating layer.

In a further embodiment, the step (B) of the above method includes the steps of (B-1) imprinting the tool foil on the insulating layer, while heating at least one of the insulating layer and the tool foil to temporarily cure the insulating layer; (B-2) removing the tool foil from the insulating layer, thereby forming the recess for the second circuit pattern in the insulating layer; and (B-3) curing the insulating layer completely.

In yet another embodiment, the tool foil further includes a pattern corresponding to an upper land for the via hole.

### BRIEF DESCRIPTION OF THE DRAWINGS

The above and other objects, features and advantages of the present invention will be more clearly understood from the following detailed description taken in conjunction with the accompanying drawings, in which:

FIGS. 1a to 1i are sectional views sequentially showing a process of fabricating a PCB using a conventional semi-additive technique;

FIGS. 2a to 2e are sectional views sequentially showing a process of fabricating a PCB using a conventional imprinting technique;

FIG. 3 is a flow chart showing a process of fabricating a PCB, according to an embodiment of the present invention;

FIGS. 4a to 4g are sectional views sequentially showing the process of fabricating the PCB, according to an embodiment of the present invention;

FIGS. 5a to 5g are sectional views sequentially showing a process of fabricating a PCB, according to another embodiment of the present invention;

FIGS. 6a to 6h are sectional views sequentially showing a process of fabricating a PCB, according to a comparative embodiment compared to the fabrication process of the present invention; and

FIG. 7 is a sectional view showing the defect caused by the fabrication process of FIGS. 6a to 6h.

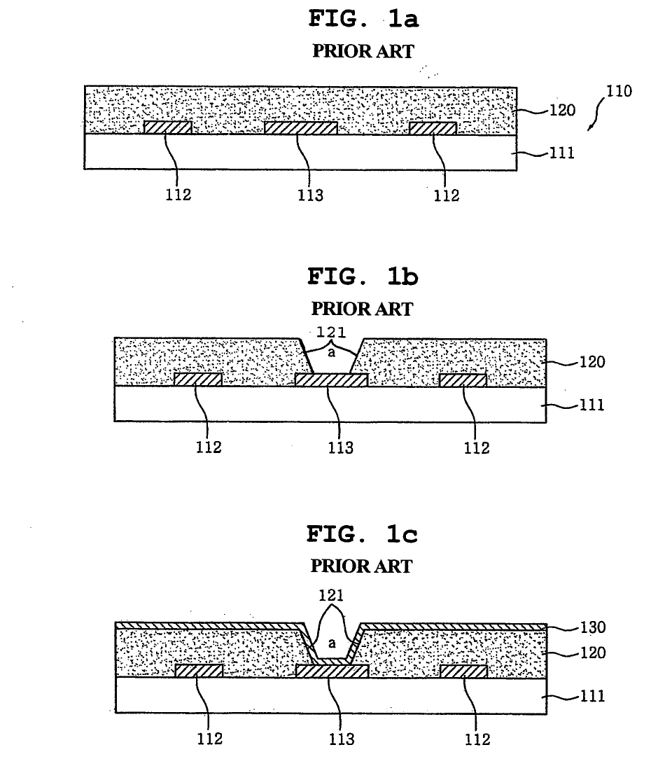

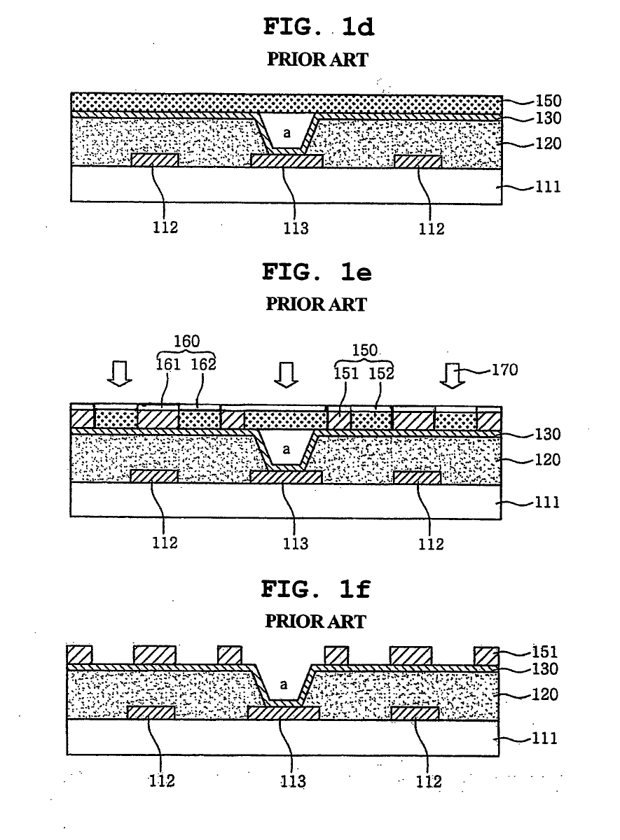

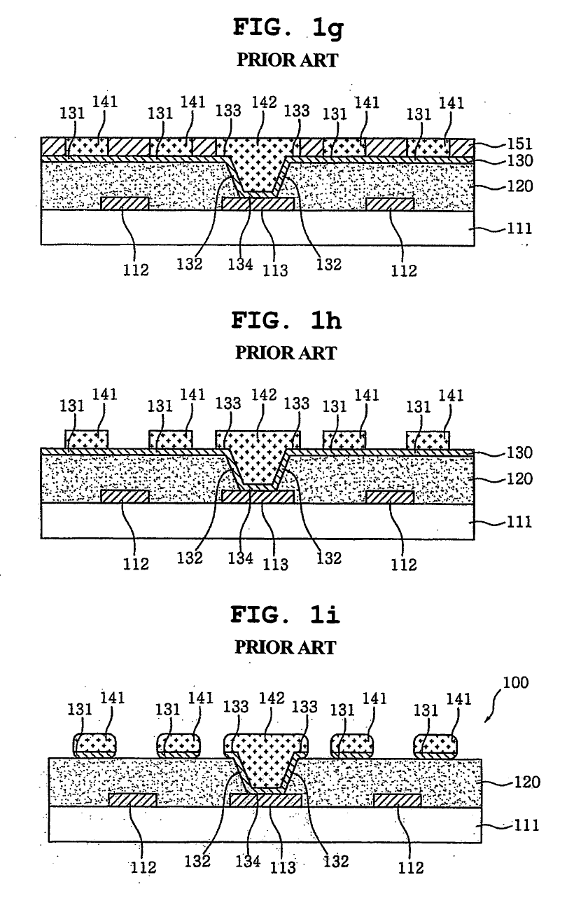

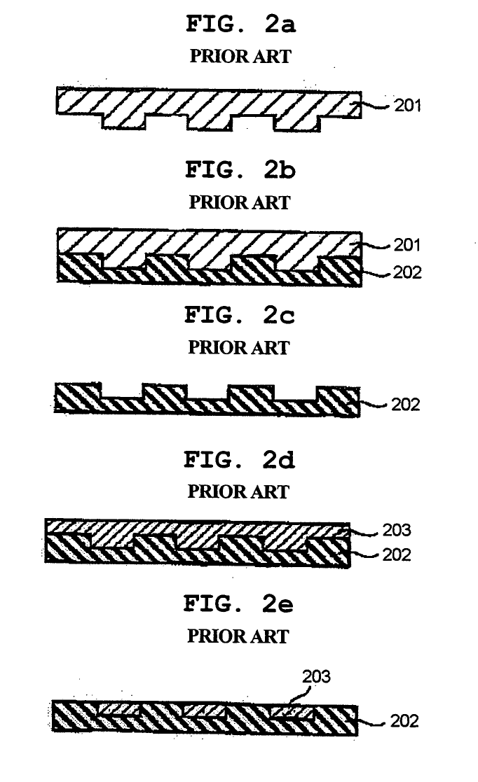

### DETAILED DESCRIPTION OF THE INVENTION

Hereinafter, a detailed description will be given of a method of fabricating a PCB according to the present invention, with reference to the appended drawings.

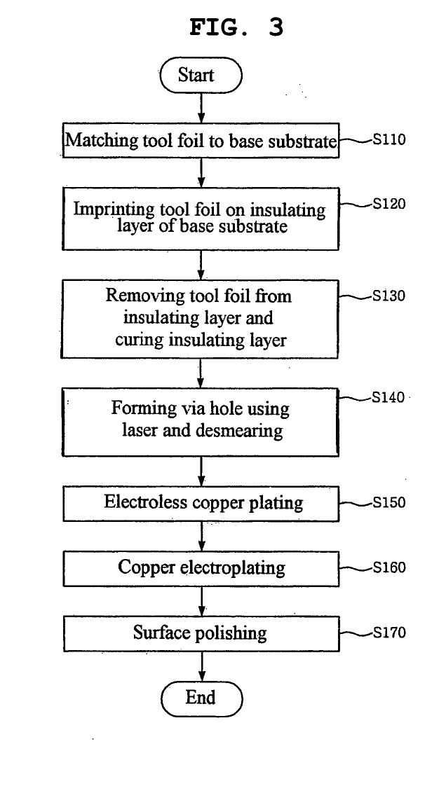

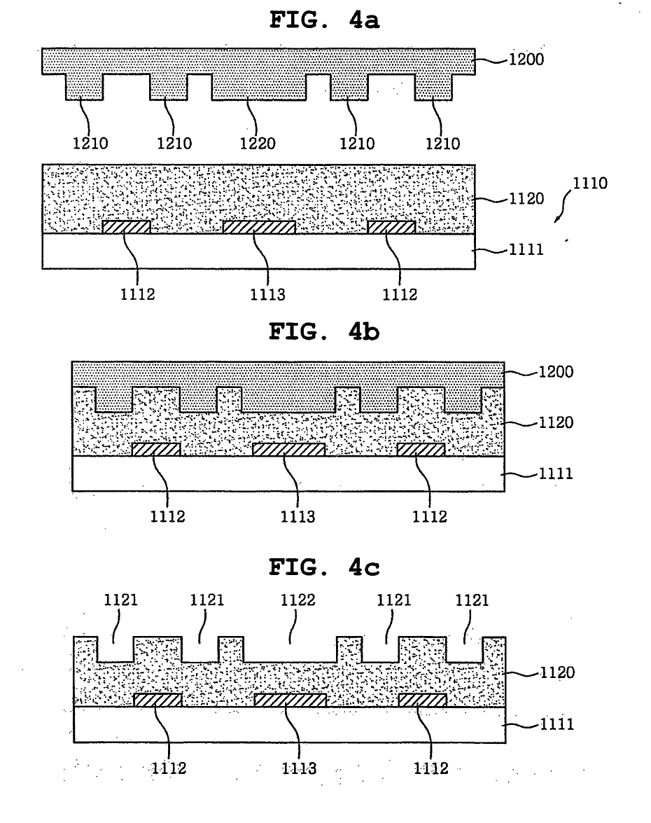

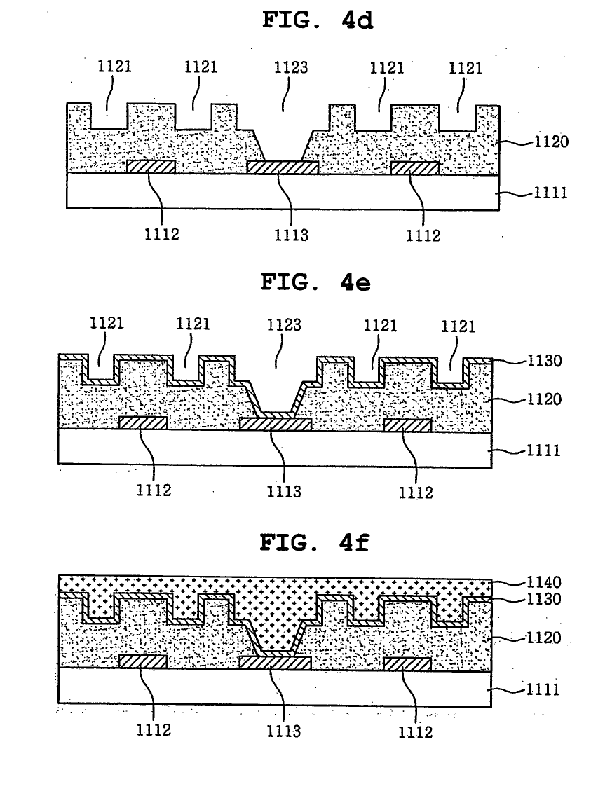

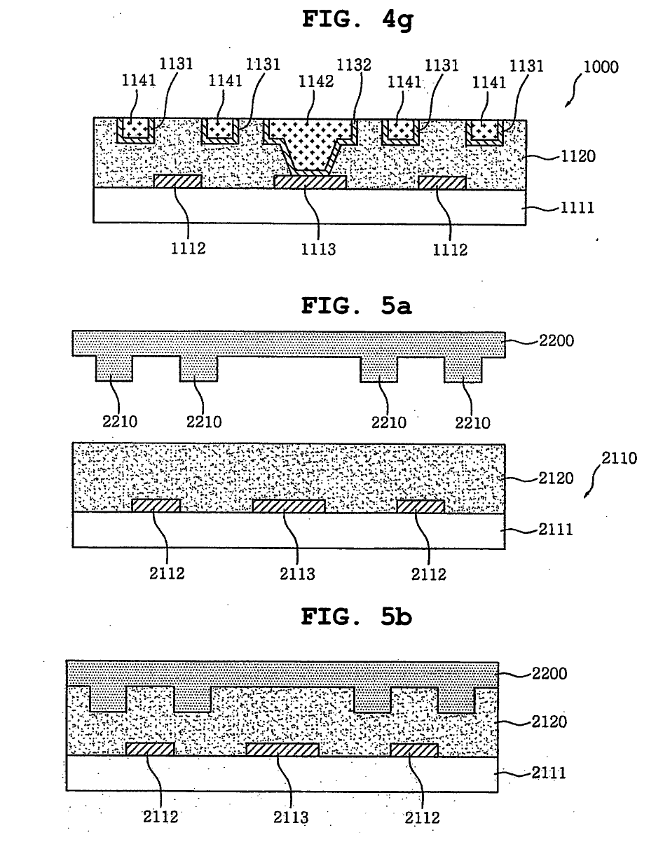

FIG. 3 is a flow chart showing a process of fabricating a PCB, according to an embodiment of the present invention, and FIGS. 4a to 4g are sectional views sequentially showing the process of fabricating the PCB, according to an embodiment of the present invention. As such, it is noted that although one surface of the PCB is processed in the drawings, both surfaces of the PCB are actually processed.

As shown in FIG. 3, the method of fabricating the PCB includes matching a tool foil to a base substrate (S110), imprinting the tool foil on an insulating layer on the base substrate (S120), removing the tool foil from the insulating layer and curing the insulating layer (S130), forming a via hole using a laser and desmearing (S140), forming an electroless copper plated layer (S150), forming a copper electroplated layer (S160), and polishing the surface of the plated layer (S170).

More specifically, in FIG. 4a, a base substrate 1110, which is a CCL having an insulating resin layer 1111 and a first circuit pattern 1112 and a lower land 1113 for a via hole formed on the insulating layer 1111, is prepared, after which a semi-cured insulating layer 1120 is laminated on the base substrate 1110. Then, a tool foil having a negative pattern corresponding to a circuit pattern is matched to the insulating layer 1120 laminated on the base substrate 1110 (S110). As such, the negative pattern includes a predetermined pattern 1210 corresponding to a second circuit pattern and a predetermined pattern 1220 corresponding to an upper land for the via hole.

Used as the base substrate 1110, the CCL is exemplified by glass/epoxy CCL, heat resistant resin CCL, paper/phenol CCL, high frequency CCL, flexible CCL, composite CCL, etc., depending on the end purpose. Of these CCLs, the glass/epoxy CCL including an insulating resin layer and copper foil layers formed on both surfaces thereof is preferably used to prepare a PCB 1000.

Although the circuit layer is formed on either surface of the base substrate 1110, a base substrate having a multi-layer structure in which a predetermined inner circuit pattern and a via hole are formed may be used, depending on the end purpose.

The tool foil 1200 is formed of a transparent material, such as SiO₂, quartz, glass or a polymer, or an opaque material, such as a semiconductor material, ceramic, metal or a polymer.

Further, the tool foil 1200 is manufactured by processing one surface of a plate to form a negative pattern. As such, the one surface of the plate is processed by electron beam lithography, photo-lithography, dicing, laser, RIE (Reactive Ion Etching) or the like.

Alternatively, the tool foil 1200 may be manufactured by separately preparing circuit patterns, and attaching them to the plate to form the negative pattern.

In an embodiment, to easily remove the tool foil 1200 from the insulating layer 1120, a release film may be attached to the surface of the negative pattern of the tool foil 1200.

In FIG. 4b, the tool foil 1200 having the negative pattern is imprinted on the insulating layer 1120 on the base substrate 1110 (S120).

In FIG. 4c, the tool foil 1200 is removed from the insulating layer 1120, whereby recesses 1121 for the second circuit pattern and a recess 1122 for the upper land for the via hole are formed in the insulating layer 1120. Subsequently, the insulating layer 1120 having the recesses 1121 and 1122 is cured using ultraviolet rays or heat (S130).

In an embodiment, while the tool foil 1200 is imprinted on the insulating layer 1120 (S120), the insulating layer 1120 or the tool foil 1200 is sufficiently heated, whereby the semi-cured insulating layer 1120 is cured.

In another embodiment, while the tool foil 1200 is imprinted on the insulating layer 1120 (S120), the insulating layer 1120 or the tool foil 1200 is sufficiently heated to temporarily cure the semi-cured insulating layer 1120, after which the insulating layer 1120 is cured using ultraviolet rays or heat (S130).

In FIG. 4d, the recess 1122 for the upper land in the insulating layer 1120 is processed using a laser, to form a via hole 1123 for circuit connection between the layers. Thereafter, a desmearing process is conducted to remove a smear created on the inner wall of the via hole 1123 by the insulating layer 1120 melted due to heat generated when forming the via hole 1123 (S140).

At this time, a laser is exemplified by a YAG (Yttrium Aluminum Garnet) laser and a CO₂ laser.

In FIG. 4e, to electrically connect the layers and form the circuit pattern on the insulating layer 1120, an electroless copper plated layer 1130 is formed on the insulting layer 1120, the recesses 1121 for the second circuit pattern and the inner wall of the via hole 1123 (S150).

The electroless copper plated layer 1130 is formed by catalyst deposition, which includes the steps of cleaning, soft etching, pre-catalysis, catalysis, activation, electroless copper plating, and oxidation prevention.

Alternatively, the electroless copper plated layer 1130 may be formed by sputtering, in which ion particles (e.g., Ar⁺) of gas generated by plasma collide with a copper target, so that the electroless copper plated layer 1130 is formed on the insulting layer 1120, the recesses 1121 for the second circuit pattern, and the inner wall of the via hole 1123.

In FIG. 4f, to fill the recesses 1121 for the second circuit pattern and the via hole 1123 with a conductive material, a copper electroplated layer 1140 is formed on the entire surface of the electroless copper plated layer 1130 (S160).

As such, the copper electroplated layer 1140 is formed in such a way that the substrate is dipped into a copper electroplating bath to perform copper electroplating using a direct current (DC) rectifier, in which the plating area is calculated and a predetermined current required to plate the calculated plating area is applied using the DC rectifier to deposit copper.

The copper electroplated layer has physical properties superior to the electroless copper plated layer, and is easily formed to be thick.

As a copper plating wire to form the copper electroplated layer 1140, a separately formed copper plating wire may be used. However, in an embodiment of the present invention, the copper plating wire to form the copper electroplated layer 1140 may consist of the electroless copper plated layer 1130.

In FIG. 4g, to remove the unnecessary copper plated layer, the surface of the copper plated layer composed of the electroless copper plated layer 1130 and the copper electroplated layer 1140 is polished until the insulating layer 1120 is exposed, thereby forming the second circuit pattern composed of the plated copper 1131 and 1141 and the via hole composed of the plated copper 1132 and 1142 (S170).

The surface polishing process is exemplified by chemical-mechanical polishing to polish the surface of the plated layer using a chemical reaction and mechanical polishing. In the chemical-mechanical polishing, the substrate in contact with a polishing pad is supplied with a polishing slurry, whereby the surface of the substrate is chemically reacted and, simultaneously, is physically flattened by the motion of a polishing table, equipped with a polishing pad, relative to a polishing head to hold the substrate.

Thereafter, laminating the insulating layer, imprinting the tool foil on the insulating layer, forming the via hole, forming the electroless copper plated layer, forming the copper electroplated layer and polishing the surface of the plated layer are repeatedly performed until the desired number of layers is obtained. Subsequently, forming a solder resist, nickel/gold plating and forming an outer appearance are further performed, thus fabricating a PCB 1000, according to an embodiment of the present invention.

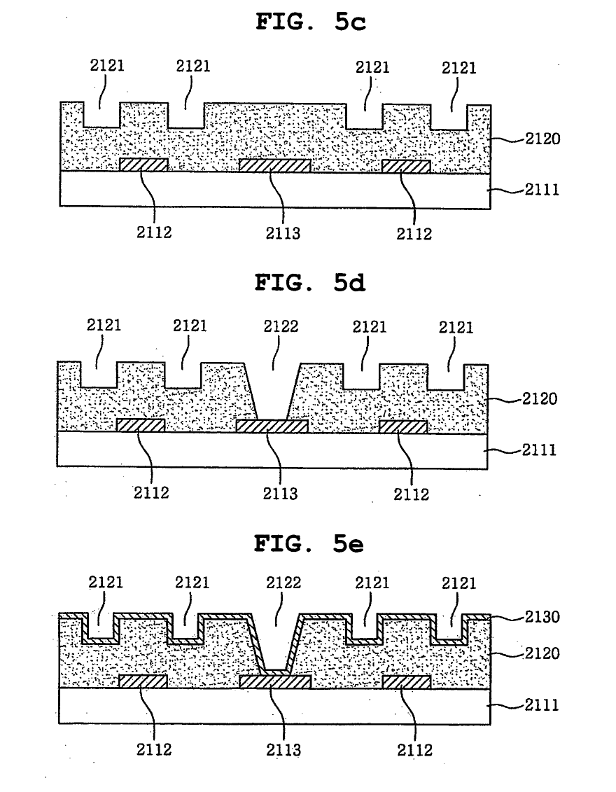

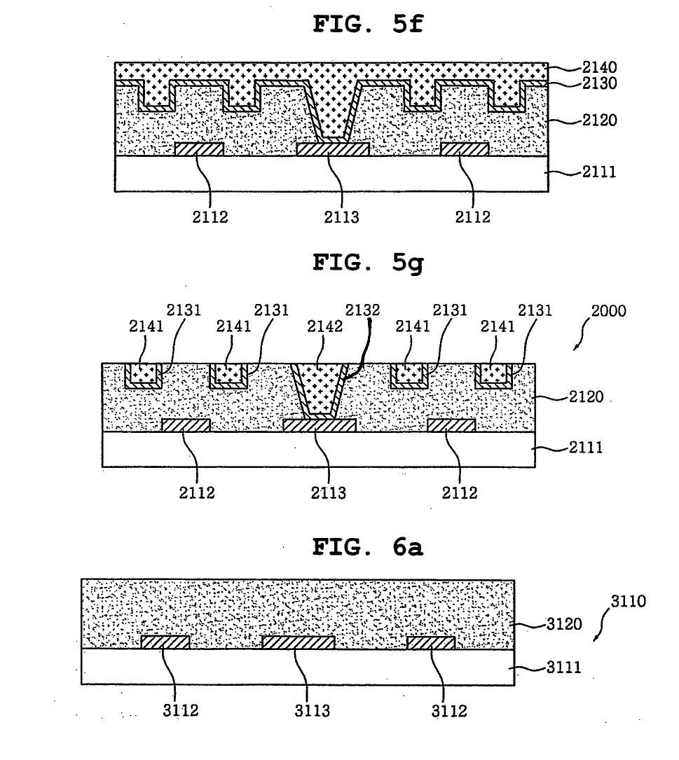

FIGS. 5a to 5g are sectional views sequentially showing a process of fabricating a PCB, according to another embodiment of the present invention. In the drawings, it is noted that although one surface of the PCB is processed, both surfaces of the PCB are actually processed.

In FIG. 5a, a base substrate 2110, which is a CCL having an insulating layer 2111 and a first circuit pattern 2112 and a lower land 2113 for a via hole formed on the insulating layer 2111, is prepared, and a semi-cured insulating layer 2120 is laminated on the base substrate 2110. Then, a tool foil 2200 having a negative pattern is matched to the insulating layer 2120 on the base substrate 2110 (S110). As such, the negative pattern includes a predetermined pattern 2210 corresponding to a second circuit pattern.

In the drawing, although the base substrate 2110 having the circuit layer on one surface thereof is shown, the base substrate 2110 having a multi-layer structure in which a predetermined inner circuit pattern and a via hole are formed may be used, depending on the end purpose.

In an embodiment, a release film may be attached to the surface of the negative circuit pattern of the tool foil 2200 to easily remove the tool foil 2200 from the insulating layer 2120.

In FIG. 5b, the tool foil 2200 having the negative pattern is imprinted on the insulating layer 2120 on the base substrate 2110 (S120).

In FIG. 5c, the tool foil 2200 is removed from the insulating layer 2120, whereby recesses 2121 for the second circuit pattern are formed in the insulating layer 2120. Subsequently, the insulating layer 2120 having the recesses 2121 is cured using ultraviolet rays or heat (S130).

In an embodiment, while the tool foil 2200 is imprinted on the insulating layer 2120 (S120), the insulating layer 2120 or the tool foil 2200 is sufficiently heated, so that the semi-cured insulating layer 2120 is cured.

In another embodiment, while the tool foil 2200 is imprinted on the insulating layer 2120 (S120), the insulating layer 2120 or the tool foil 2200 is sufficiently heated to temporarily cure the semi-cured insulating layer 2120, after which the insulating layer 2120 is cured using ultraviolet rays or heat (S130).

In FIG. 5d, the insulating layer 2120 is processed using a laser, to form a via hole 2122 for circuit connection between the layers. Then, a desmearing process is conducted to remove a smear created on the inner wall of the via hole 2122 by the insulating layer 2120 melted due to heat generated upon formation of the via hole 2122 (S140).

Used in the present invention, the laser includes, for example, a YAG laser or a CO₂ laser.

In FIG. 5e, to electrically connect the layers and form the circuit pattern on the insulating layer 2120, an electroless copper plated layer 2130 is formed on the insulting layer 2120, the recesses 2121 for the second circuit pattern, and the inner wall of the via hole 2122 (S150).

In such a case, the electroless copper plated layer 2130 is formed using catalyst deposition or sputtering.

In FIG. 5f, to fill the recesses 2121 for the second circuit pattern and the via hole 2122 with a conductive material, a copper electroplated layer 2140 is formed on the entire surface of the electroless copper plated layer 2130 (S160).

As such, the copper electroplated layer 2140 is formed in such a way that the substrate is dipped into a copper electroplating bath to perform copper electroplating using a DC rectifier, in which the plating area is calculated and a predetermined current required to plate the calculated plating area is applied using the DC rectifier to deposit copper.

In an embodiment, the copper plating wire to form the copper electroplated layer 2140 may consist of the electroless copper plated layer 2130.

In FIG. 5g, to remove the unnecessary copper plated layer, the surface of the copper plated layer composed of the electroless copper plated layer 2130 and the copper electroplated layer 2140 is polished using chemical-mechanical polishing until the insulating layer 2120 is exposed, thereby forming the second circuit pattern composed of the plated copper 2131 and 2141 and the via hole composed of the plated copper 2132 and 2142 (S170).

Thereafter, laminating the insulating layer, imprinting the tool foil on the insulating layer, forming the via hole, forming the electroless copper plated layer, forming the copper electroplated layer and polishing the surface of the plated layer are repeatedly performed until the desired number of layers is obtained. Subsequently, forming a solder resist, nickel/gold plating and forming an outer appearance are further performed, thus fabricating a PCB 2000, according to the current embodiment of the present invention.

Compared to the process of fabricating the PCB shown in FIGS. 4a to 4g, the process of fabricating the PCB shown in FIGS. 5a to 5g forms a landless via hole having no upper land for the via hole 2122, since the negative pattern of the tool foil 2200 has no pattern corresponding to the upper land for the via hole 2122.

Accordingly, the process of fabricating the PCB shown in FIGS. 5a to 5g is advantageous because it can form the second circuit pattern composed of the plated copper 2131 and 2141 at a higher density, due to the absence of the upper land for the via hole 2122, unlike the process of fabricating the PCB shown in FIGS. 4a to 4g.

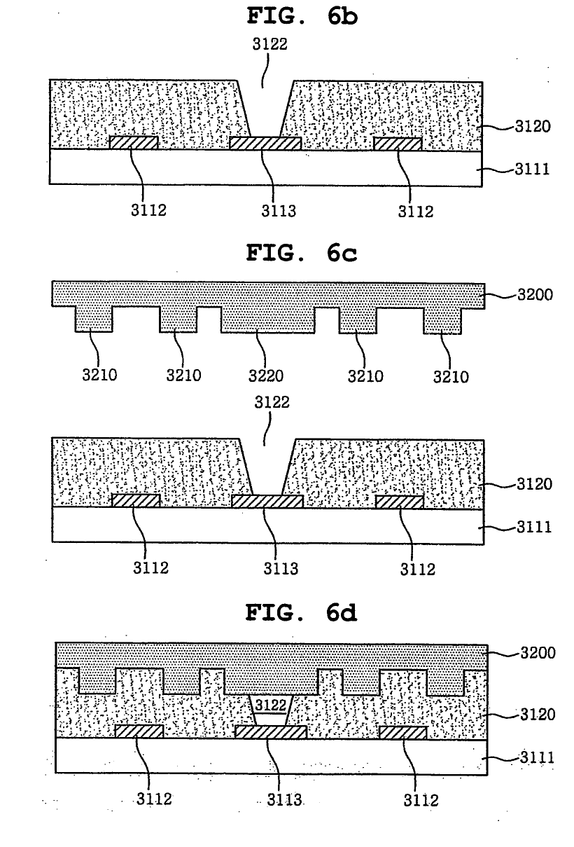

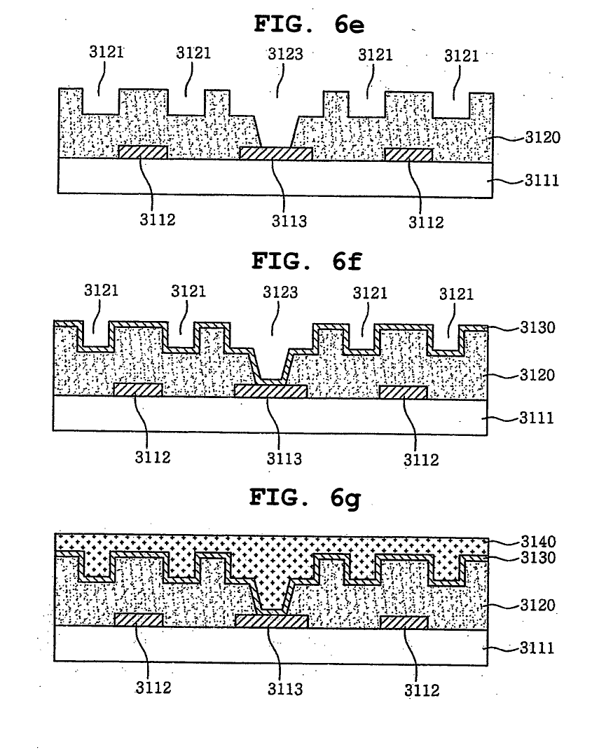

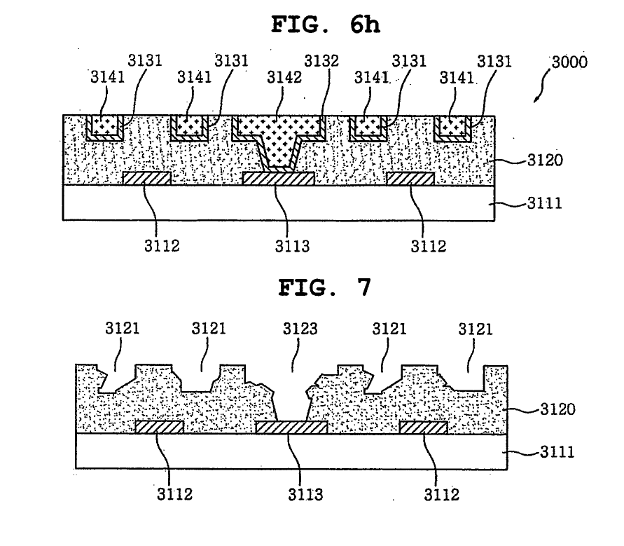

FIGS. 6a to 6h are sectional views sequentially showing a process of fabricating a PCB, according to a comparative embodiment for comparison with the fabrication methods of the present invention, which is combined processes of forming a via hole using a laser in a conventional semi-additive technique and of fabricating a PCB disclosed in Japanese Patent Laid-open Publication No. 2001-320150. In addition, FIG. 7 is a sectional view showing the problem caused by the fabrication process of the PCB shown in FIGS. 6a to 6h.

In FIG. 6a, an insulating layer 3120 is laminated on a CCL 3110 having an insulating resin layer 3111 and a first circuit pattern 3112 and a lower land 3113 for a via hole formed on the insulating layer 3111.

In FIG. 6b, the insulating layer 3120 is processed using a laser to form a via hole 3122 for circuit connection between the layers. Then, a desmearing process is conducted to remove a smear created on the inner wall of the via hole 3122 by the insulating layer 3120 melted due to heat generated when the via hole 3122 is formed.

In FIG. 6c, a tool foil 3200 having a negative pattern which consists of a predetermined pattern 3210 corresponding to a second circuit pattern and a predetermined pattern 3220 corresponding to an upper land for the via hole is matched to the substrate 3100 having the via hole 3122.

In FIG. 6d, the tool foil 3200 having a negative pattern is imprinted on the insulating layer 3120 on the substrate 3100.

In FIG. 6e, the tool foil 3200 is removed from the insulating layer 3120, thereby forming recesses 3121 for the second circuit pattern in the insulating layer 3120 and a via hole 3123 through the insulating layer 3120.

In FIG. 6f, to electrically connect the layers and form the circuit pattern on the insulating layer 3120, an electroless copper plated layer 3130 is formed on the insulting layer 3120, the recesses 3121 for the second circuit pattern, and the inner wall of the via hole 3123.

In FIG. 6g, to fill the recesses 3121 for the second circuit pattern and the via hole 3123 with a conductive material, a copper electroplated layer 3140 is formed throughout the electroless copper plated layer 3130.

In FIG. 6h, to remove the unnecessary copper plated layer, the surface of the copper plated layer composed of the electroless copper plated layer 3130 and the copper electroplated layer 3140 is polished until the insulating layer 3120 is exposed, thereby forming the second circuit pattern composed of the plated copper 3131 and 3141 and the via hole composed of the plated copper 3132 and 3142.

Then, laminating the insulating layer, forming the via hole, imprinting the tool foil on the insulating layer, forming the electroless copper plated layer, forming the copper electroplated layer and polishing the surface of the plated layer are repeatedly performed until the desired number of layers is obtained. Subsequently, forming a solder resist, nickel/gold plating and forming an outer appearance are further performed, thus fabricating a PCB 3000, according the comparative embodiment of the present invention.

In the fabrication method of the PCB shown in FIGS. 6a to 6h, the insulating layer 3120 should be completely cured to form the via hole 3122 using a laser as shown in FIG. 6b. In addition, the insulating layer 3120 should be semi-cured to imprint the tool foil 3200 on the insulating layer 3120 as shown in FIG. 6d.

If the insulating layer 3120 is completely cured to form the via hole 3122 using a laser as in FIG. 6b, the imprinting of the tool foil 3200 on the insulating layer 3120 as shown in FIG. 6d cannot be carried out. Thus, as shown in FIG. 7, the portions of the recesses 3121 for the second circuit pattern and the via hole 3123 may break down or be damaged.

Meanwhile, if the insulating layer 3120 is maintained in the state of being semi-cured to imprint the tool foil 3200 on the insulating layer 3120 as apparent from FIG. 6d, the forming of the via hole 3122 using a laser as in FIG. 6b cannot be conducted. This is because the semi-cured insulating layer 3120 located around the via hole 3122 is melted by the laser used to form the via hole 3122, and hence, the via hole 3122 having a desired size cannot be formed.

To overcome the problems, the method of fabricating the PCB, according to the present invention, adopts an imprinting process, in which the via hole is formed using a laser in the course of forming the circuit pattern.

Therefore, in the method of fabricating the PCB according to the present invention, when the tool foil 1200 or 2200 is imprinted on the insulating layer 1120 or 2120 shown in FIG. 4b or 5b, the insulating layer 1120 or 2120 is in the state of being semi-cured, and thus, the recesses 1121 or 2121 for the second fine circuit pattern or the recess 1122 for the upper land can be formed.

In the method of fabricating the PCB according to the present invention, when the via hole 1123 or 2123 is formed using a laser as shown in FIG. 4d or 5d, the insulating layer 1120 or 2120 is in the state of being completely cured, and thus, the via hole having a desired size can be formed.

In the method of fabricating the PCB according to the present invention, since the process of forming the circuit pattern using imprinting and the process of forming the via hole using a laser may exhibit synergistic effects, a fine circuit pattern and a via hole having no residue can be formed.

Additionally, in the method of fabricating the PCB according to the present invention, the copper plated layer includes a plated layer consisting mainly of copper, as well as a plated layer consisting completely of pure copper. This can be confirmed by analyzing a chemical composition of the copper plated layer using an analyzing device, such as EDAX (Energy Dispersive Analysis of X-ray).

Further, in the method of fabricating the PCB according to the present invention, the plated layer may be formed of a conductive material, such as gold (Au), nickel (Ni), tin (Sn), etc., depending on the end purpose, in addition to copper (Cu).

As described above, the present invention provides a method of fabricating a PCB, in which the circuit pattern is formed by imprinting and thus is fine and has regular width therebetween. In addition, the PCB has a flat structure.

In the method of fabricating the PCB according to the present invention, the via hole is formed using a laser and then a desmearing process is performed. Hence, the via hole has no residue.

In the method of fabricating the PCB according to the present invention, since the circuit pattern is embedded in the insulating layer, it is not delaminated or damaged.

In the method of fabricating the PCB according to the present invention, the tool foil is fabricated at low cost and is easily managed, owing to having the negative pattern corresponding to the plane circuit pattern.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A method of fabricating a printed circuit board, comprising the steps of:
laminating a semi-cured insulating layer on a base substrate having a first circuit pattern and a lower land for a via hole, and matching a tool foil having a predetermined pattern corresponding to a second circuit pattern to the base substrate having the insulating layer laminated thereon;
imprinting the tool foil on the insulating layer and completely curing the insulating layer, to form a recess for the second circuit pattern in the insulating layer;
forming a via hole through the insulating layer on the lower land of the base substrate using a laser;
forming an electroless plated layer on the insulating layer, the recess for the second circuit pattern, and the inner wall of the via hole;
forming an electroplated layer on the electroless plated layer; and
polishing the electroless plated layer and the electroplated layer until the insulating layer is exposed.

2. The method as set forth in claim 1, wherein the imprinting step comprises the steps of:
imprinting the tool foil on the insulating layer;
removing the tool foil from the insulating layer, thereby forming the recess for the second circuit pattern in the insulating layer; and
curing the insulating layer completely.

3. The method as set forth in claim 1, wherein the imprinting step comprises the steps of:
imprinting the tool foil on the insulating layer, while heating at least one of the insulating layer and the tool foil to completely cure the insulating layer; and
removing the tool foil from the insulating layer, thereby forming the recess for the second circuit pattern in the insulating layer.

4. The method as set forth in claim 1, wherein the imprinting step comprises the steps of:
imprinting the tool foil on the insulating layer, while heating at least one of the insulating layer and the tool foil to temporarily cure the insulating layer;
removing the tool foil from the insulating layer, thereby forming the recess for the second circuit pattern in the insulating layer; and
curing the insulating layer completely.

5. The method as set forth in claim 1, wherein the tool foil further comprises a pattern corresponding to an upper land for the via hole.
